(19) United States
(12) Patent Application Publication
(10) Pub. No.: US 2020/0210670 A1
(43) Pub. Date: Jul. 2, 2020

(54) OPTICAL FINGERPRINT RECOGNITION DEVICE

(71) Applicant: Wuhan China Star Optoelectronics Technology Co., Ltd., Wuhan (CN)

(72) Inventors: Fancheng LIU, Wuhan (CN); Jian HE, Wuhan (CN)

(73) Assignee: Wuhan China Star Optoelectronics Technology Co., Ltd., Wuhan (CN)

(21) Appl. No.: 16/470,691

(22) PCT Filed: Mar. 8, 2019
(86) PCT No.: PCT/CN2019/077405

§ 371 Date: Jun. 18, 2019

(30) Foreign Application Priority Data
Dec. 29, 2018 (CN) 201811633669.9

(51) Int. Cl. G06K 9/00; G02F 1/1334; G02B 27/30; H01L 27/32; H01L 27/146

(52) U.S. Cl. CPC G06K 9/0004; G02F 1/1334; G02B 27/30; H01L 27/3234; H01L 27/3232; G02F 2201/44; H01L 27/14625; H01L 27/14621; H01L 27/14618; G02F 2001/13345; H01L 27/14678

(57) ABSTRACT

An optical fingerprint recognition device includes a substrate, a light-sensitive element, a cover, and a collimation layer disposed between the cover and the substrate. The collimation layer is formed by dispersing liquid crystals in a solid-state organic polymer. The collimation layer is disposed to reduce signal noise, and improve definition of a fingerprint on the light-sensitive element. In addition, in comparison with a current lens and the like, a full-surface collimation layer has such advantages as crashworthiness and relative displacement, and can improve reliability of fingerprint recognition.

### FIELD OF INVENTION

The present invention relates to the field of fingerprint recognition technologies, and in particular, to an optical fingerprint recognition device.

### BACKGROUND OF INVENTION

With ever-changing technology, mobile phones and other mobile terminals have increasingly high screen ratios, and full-screen mobile terminals have become a trend of development. For fingerprint recognition of full-screen mobile terminals, a conventional capacitive fingerprint cannot penetrate cover glass having a thickness of more than 0.5 millimeter, and therefore no longer adapts to a development trend of the full-screen mobile terminals, while an optical fingerprint with good penetration has become a new technical direction.

At present, for an optical fingerprint recognition design of a full screen, generally, an optical fingerprint recognition module is disposed below a display area. Light for fingerprint recognition needs to pass through at least a glass cover in contact with a finger. Because of a particular thickness of the glass cover, the light is subject to severe refraction and scattering when the light returns through the glass cover. Consequently, a fingerprint image cannot be clearly imaged on an optical fingerprint chip.

### SUMMARY OF INVENTION

The present invention provides an optical fingerprint recognition device, to resolve a problem that for a current optical fingerprint recognition module, because light for fingerprint recognition needs to pass through different mediums during transmission, reflected light is refracted and scattered, affecting image definition of a fingerprint on an optical fingerprint chip, thereby harming reliability of fingerprint recognition.

To resolve the foregoing problem, the technical solutions provided in the present invention are as follows:

The present invention provides an optical fingerprint recognition device, including a substrate, a light-sensitive element, a cover, and a collimation layer. The light-sensitive element is disposed on the substrate. The cover is disposed on the light-sensitive element. The collimation layer is disposed between the cover and the light-sensitive element. Two opposite surfaces of the collimation layer are provided with a first electrode layer and a second electrode layer respectively. The collimation layer is formed by dispersing liquid crystals in a solid-state organic polymer.

In at least one embodiment of the present invention, a material of the collimation layer is one of polymer dispersed liquid crystals (PDLC) and polymer network liquid crystals (PNLC).

In at least one embodiment of the present invention, the optical fingerprint recognition device further includes an adhesive layer, and the adhesive layer is disposed between the cover and the collimation layer.

In at least one embodiment of the present invention, a refractive index of the liquid crystal molecule in a major axis direction is equal to each of a refractive index of the polymer, a refractive index of the adhesive layer, and a refractive index of the cover.

In at least one embodiment of the present invention, the optical fingerprint recognition device further includes a backlight module, and the backlight module is disposed on one side of the substrate away from the light-sensitive element.

In at least one embodiment of the present invention, the optical fingerprint recognition device further includes an organic light-emitting diode (OLED) display layer, and the OLED display layer is disposed between the cover and the collimation layer.

In at least one embodiment of the present invention, a refractive index of the liquid crystal molecule in a major axis direction is equal to each of a refractive index of the polymer, a refractive index of the OLED display layer, and a refractive index of the cover.

In at least one embodiment of the present invention, a side surface of the substrate close to the light-sensitive element is provided with a light filter layer.

The present invention further provides an optical fingerprint recognition device, including a substrate, a light-sensitive element, a cover, and a collimation layer. The light-sensitive element is disposed on the substrate. The cover is disposed on the light-sensitive element. The collimation layer is disposed between the cover and the substrate. The collimation layer is formed by dispersing liquid crystals in a solid-state organic polymer.

In at least one embodiment of the present invention, a material of the collimation layer is one of PDLCs and PNLCs.

In at least one embodiment of the present invention, two opposite surfaces of the collimation layer are provided with a first electrode layer and a second electrode layer respectively.

In at least one embodiment of the present invention, the collimation layer is disposed between the cover and the light-sensitive element.

In at least one embodiment of the present invention, the optical fingerprint recognition device further includes an adhesive layer, and the adhesive layer is disposed between the cover and the collimation layer.

In at least one embodiment of the present invention, a refractive index of the liquid crystal molecule in a major axis direction is equal to each of a refractive index of the polymer, a refractive index of the adhesive layer, and a refractive index of the cover.

In at least one embodiment of the present invention, the optical fingerprint recognition device further includes a backlight module, and the backlight module is disposed on one side of the substrate away from the light-sensitive element.

In at least one embodiment of the present invention, the optical fingerprint recognition device further includes an OLED display layer, and the OLED display layer is disposed between the cover and the collimation layer.

In at least one embodiment of the present invention, a refractive index of the liquid crystal molecule in a major axis direction is equal to each of a refractive index of the polymer, a refractive index of the OLED display layer, and a refractive index of the cover.

In at least one embodiment of the present invention, a side surface of the substrate close to the light-sensitive element is provided with a light filter layer.

Beneficial effects of the present invention are described as follows: Based on the optical fingerprint recognition device provided in the present invention, the collimation layer prepared by using PDLCs is disposed to reduce signal noise, and improve definition of a fingerprint on the light-sensitive element. In addition, in comparison with a current lens and the like, a full-surface collimation layer has such advantages as crashworthiness and relative movement, and can improve reliability of fingerprint recognition.

### BRIEF DESCRIPTION OF DRAWINGS

To describe the technical solutions in the embodiments or in the prior art more clearly, the following briefly describes the accompanying drawings required for describing the embodiments or the prior art. Apparently, the accompanying drawings in the following description show merely some embodiments of the present invention, and a person of ordinary skill in the art may still derive other drawings from these accompanying drawings without creative efforts.

FIG. 1 is a schematic structural diagram of an optical fingerprint recognition device according to Embodiment 1 of the present invention.

FIG. 2 is a schematic structural diagram of an optical fingerprint recognition device according to Embodiment 2 of the present invention.

FIG. 3 is a top view of a first electrode layer according to Embodiment 2 of the present invention.

FIG. 4 is a schematic structural diagram of an optical fingerprint recognition device according to Embodiment 3 of the present invention embodiment.

### DETAILED DESCRIPTION OF PREFERRED EMBODIMENTS

The following embodiments are described with reference to the accompanying drawings, and are used to exemplify specific embodiments for implementation of the present invention. Terms about directions mentioned in the present invention, such as “upper”, “lower”, “front”, “rear”, “left”, “right”, “in”, “out”, and “side surface” merely refer to directions in the accompanying drawings. Therefore, the used terms about directions are used to describe and understand the present invention, and are not intended to limit the present invention. In the figures, units having similar structures are represented by using a same reference number.

In the present invention, for a problem that for a current optical fingerprint recognition module, because light for fingerprint recognition needs to pass through different mediums during transmission, reflected light is refracted and scattered, affecting image definition of a fingerprint on an optical fingerprint chip, and affecting reliability of optical fingerprint recognition, the embodiments can solve the disadvantage.

### Embodiment 1

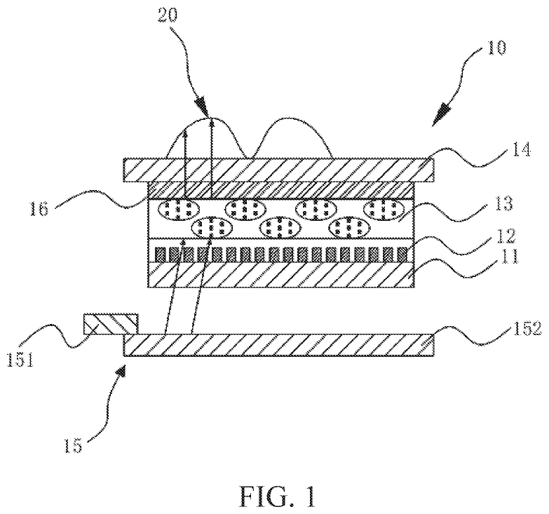

As shown in FIG. 1, the present invention provides an optical fingerprint recognition device 10, including a substrate 11, a light-sensitive element 12, a collimation layer 13, a cover 14, and a backlight module 15.

The light-sensitive element 12 is disposed on the substrate 11. The cover 14 is disposed on the light-sensitive element 12. The cover 14 is located on the top of the fingerprint recognition device 10, and achieves a function of packaging and protecting the device. The cover 14 is transparent glass, and the cover 14 contacts with a human fingerprint 20.

The backlight module 15 is disposed on side of the substrate 11 away from the light-sensitive element 12. The backlight module 15 provides a light source for optical fingerprint recognition.

The collimation layer 13 is formed by dispersing liquid crystals in a solid-state organic polymer. In the present embodiment, a material of the collimation layer 13 is PDLCs. In another embodiment, a material of the collimation layer 13 may be PNLCs.

In the present embodiment, the collimation layer 13 is disposed between the cover 14 and the light-sensitive element 12. A film layer thickness of the collimation layer 13 is 5-50 micrometers. In another embodiment, the collimation layer may be disposed between the light-sensitive element 12 and the backlight module 15.

A liquid crystal in the collimation layer 13 is a nematic phase liquid crystal, and a refractive index of the organic polymer is equal to a refractive index of the liquid crystal molecule in a major axis direction.

The collimation layer 13 is a full-surface PDLC film, and is designed with no pattern. The PDLC film has a feature of selective scattering, and scatters incident light in a direction at a large angle. In comparison of a current collimation layer such as a lens, the PDLC film has such advantages as crashworthiness and relative displacement, and can further improve reliability of optical fingerprint recognition.

The optical fingerprint recognition device further includes an adhesive layer 16, disposed between the cover 14 and the collimation layer 13. The adhesive layer 16 is an optical clear adhesive, used to adhere the cover 14 to a device below the cover 14.

A refractive index of a liquid crystal molecule in the collimation layer 13 in a major axis direction is equal to a refractive index of the adhesive layer 16 and a refractive index of the cover 14.

A voltage is applied to each of upper and lower ends of the collimation layer 13, so that the liquid crystal is deflected to a specified angle (perpendicular to a surface of the PDLC film), and then UV curing is performed. After liquid crystal alignment is performed on the PDLC film, liquid crystal molecules in the film are arranged orderly. When an angle of incidence is zero degrees, transmittance of the PDLC film is approximately 80%. The transmittance decreases as the angle of incidence increases.

In a direction perpendicular to the surface of the PDLC film, the refractive index of the liquid crystal molecule along the major axis is equal to each of the refractive index of the organic polymer, the refractive index of the adhesive layer 16, and the refractive index of the cover 14, and is not affected by a refractive index difference and a gap between liquid crystal molecules. Therefore, no scattering is caused. In a direction at a large angle, a larger angle leads to a larger difference between the refractive indexes of the liquid crystal and the organic polymer, and stronger scattering. Therefore, the collimation layer 13 using the PDLCs as a material helps reduce interference of light in a direction at a large angle, and helps reduce signal noise.

In another embodiment, electrodes may be disposed on upper and lower surfaces of the collimation layer 13, to directly apply a voltage to the collimation layer 13. The disposed electrode structure may also be used for fingerprint security. In a power-off state, the liquid crystals in the collimation layer 13 are in a disordered state, and form excessively strong scattering. Consequently, unlocking cannot be implemented.

The optical fingerprint recognition device 10 in the present embodiment is a liquid crystal display device having an optical fingerprint recognition function. The substrate 11 is a thin film transistor (TFT) array substrate. The backlight module 15 includes a backlight source 151 and a light guide plate 152. The backlight module 15 is a side backlight module, and provides a light source for fingerprint recognition and further provides a light source for a liquid crystal display module.

### Embodiment 2

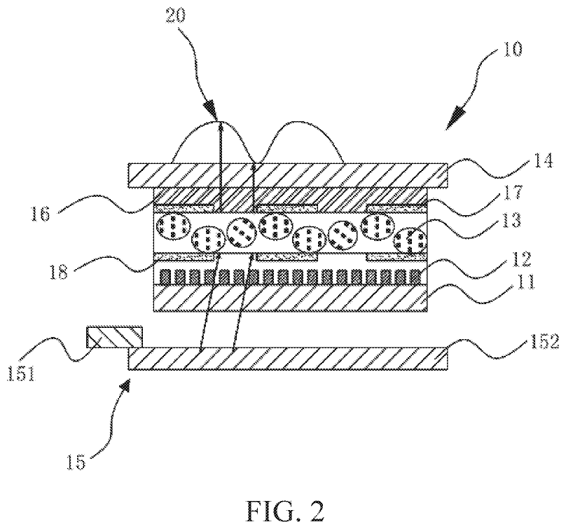

As shown in FIG. 2, a difference from Embodiment 1 lies in that, two opposite surfaces of the collimation layer 13 are provided with a first electrode layer 17 and a second electrode layer 18 respectively. The first electrode layer 17 is disposed on a side surface (the upper surface) of the collimation layer 13 away from the substrate 11. The second electrode layer 18 is disposed on a side surface (the lower surface) of the collimation layer 13 close to the substrate 11. Electrode patterns of the first electrode layer 17 and the second electrode layer 18 are the same and are disposed correspondingly. A material of each of the first electrode layer 17 and the second electrode layer 18 is indium tin oxide (ITO).

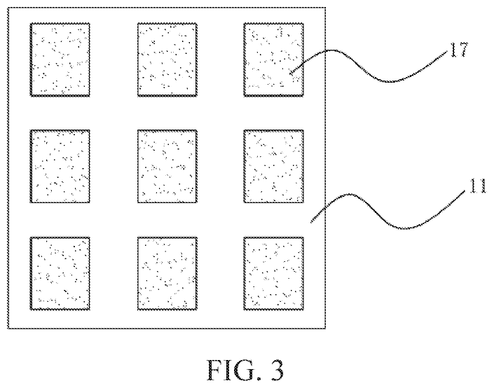

As shown in FIG. 3, the electrode pattern of the first electrode layer 17 is small electrode blocks distributed in an array. A length and a width of the small electrode block may be 2-100 micrometers. A ratio of a line spacing and a column spacing between the small electrode blocks may be set to 2:1 to 1:1. A size of the electrode pattern may be designed based on a size of a pixel electrode on the light-sensitive element 12. A smaller pixel electrode on the light-sensitive element 12 indicates a larger quantity of pixel electrodes on the light-sensitive element 12 corresponding to each small electrode block, and higher accuracy of fingerprint recognition. The device can be applied to a complex environment. Generally, one small electrode block corresponds to one to 25 pixel electrodes arranged in a matrix.

After voltages are applied to two ends of each of the first electrode layer 17 and the second electrode layer 18, liquid crystal molecules corresponding to the two electrode layers are deflected to an angle to be perpendicular to the surface of the PDLC film along the major axis. Liquid crystal molecules corresponding to a gap between the small electrode blocks are arranged in a disordered state, light scattering is strong, and transmittance is low, so that light irradiating a surface of the glass cover 14 is vertical light. Spaced electrode patterns arranged in an array help reduce interference of oblique light, to reduce signal noise and improve definition of fingerprint imaging.

### Embodiment 3

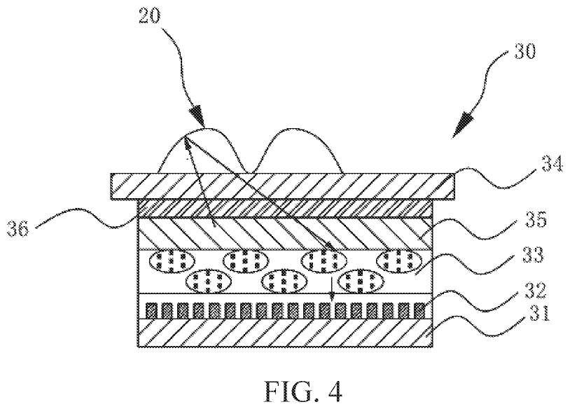

As shown in FIG. 4, the present embodiment provides an optical fingerprint recognition device 30, including a substrate 31, a light-sensitive element 32, a collimation layer 33, an OLED display layer 35, an adhesive layer 36, and a cover 34.

The light-sensitive element 33 is disposed on the substrate 31. The collimation layer 33 is disposed on the light-sensitive element 32. The cover 34 is disposed on the collimation layer 33. The OLED display layer 35 is disposed between the collimation layer 33 and the cover 34.

The adhesive layer 36 is disposed between the cover 34 and the OLED display layer 35, and is configured to adhere the cover 34 to the OLED display layer 35.

The substrate 31 may be a flexible substrate. The cover 34 is transparent glass and is configured to package and protect the device, and contacts with a human fingerprint 20.

The collimation layer 35 is a PDLC film. A refractive index of a liquid crystal molecule in the collimation layer 35 in a major axis direction is equal to each of a refractive index of a polymer, a refractive index of the adhesive layer 36, a refractive index of the OLED display layer 35, and a refractive index of the cover 34.

The OLED display layer is configured to not only display an image, but also provide a light source for fingerprint recognition, to implement light collimation by using selective scattering of the PDLC film.

A light filter layer may be disposed between the collimation layer 33 and the substrate 31. Specifically, the light filter layer (not shown) is disposed on a side surface of the substrate 31 close to the light-sensitive element 32, and is configured to filter visible light entering from a direction of the substrate 31, and specifically, filter out light whose wavelength is greater than 580 nanometers.

In another embodiment, refer to Embodiment 2, and upper and lower surfaces of the collimation layer 33 are provided with electrode patterns. A specific structure is not described in details again herein.

Beneficial effects: Based on the optical fingerprint recognition device provided in the present invention, the collimation layer prepared by using PDLCs is disposed to reduce signal noise, and improve definition of a fingerprint on the light-sensitive element. In addition, in comparison with a current lens and the like, a full-surface collimation layer has such advantages as crashworthiness and relative movement, and can improve reliability of fingerprint recognition.

In conclusion, the present invention has been disclosed above through preferred embodiments; however, the preferred embodiments are not intended to limit the present invention, and a person of ordinary skill in the art can make various modifications and improvements without departing from the spirit and scope of the present invention; therefore, the protection scope of the present invention should be subject to the scope defined by the claims.

What is claimed is:

1. An optical fingerprint recognition device, comprising:
a substrate;
a light-sensitive element, disposed on the substrate;
a cover, disposed on the light-sensitive element; and
a collimation layer, disposed between the cover and the light-sensitive element, wherein two opposite surfaces of the collimation layer are provided with a first electrode layer and a second electrode layer respectively, wherein
the collimation layer is formed by dispersing liquid crystals in a solid-state organic polymer.

2. The optical fingerprint recognition device according to claim 1, wherein a material of the collimation layer is one of polymer dispersed liquid crystals (PDLC) and polymer network liquid crystals (PNLC).

3. The optical fingerprint recognition device according to claim 1, wherein the optical fingerprint recognition device further comprises an adhesive layer, and the adhesive layer is disposed between the cover and the collimation layer.

4. The optical fingerprint recognition device according to claim 3, wherein a refractive index of the liquid crystal molecule in a major axis direction is equal to each of a refractive index of the polymer, a refractive index of the adhesive layer, and a refractive index of the cover.

5. The optical fingerprint recognition device according to claim 4, wherein the optical fingerprint recognition device further comprises a backlight module, and the backlight module is disposed on one side of the substrate away from the light-sensitive element.

6. The optical fingerprint recognition device according to claim 1, wherein the optical fingerprint recognition device further comprises an organic light-emitting diode (OLED) display layer, and the OLED display layer is disposed between the cover and the collimation layer.

7. The optical fingerprint recognition device according to claim 6, wherein a refractive index of the liquid crystal molecule in a major axis direction is equal to each of a refractive index of the polymer, a refractive index of the OLED display layer, and a refractive index of the cover.

8. The optical fingerprint recognition device according to claim 7, wherein a side surface of the substrate close to the light-sensitive element is provided with a light filter layer.

9. An optical fingerprint recognition device, comprising:
a substrate;
a light-sensitive element, disposed on the substrate;
a cover, disposed on the light-sensitive element; and
a collimation layer, disposed between the cover and the substrate, wherein
the collimation layer is formed by dispersing liquid crystals in a solid-state organic polymer.

10. The optical fingerprint recognition device according to claim 9, wherein a material of the collimation layer is one of polymer dispersed liquid crystals (PDLC) and polymer network liquid crystals (PNLC).

11. The optical fingerprint recognition device according to claim 9, wherein two opposite surfaces of the collimation layer are provided with a first electrode layer and a second electrode layer respectively.

12. The optical fingerprint recognition device according to claim 9, wherein the collimation layer is disposed between the cover and the light-sensitive element.

13. The optical fingerprint recognition device according to claim 12, wherein the optical fingerprint recognition device further comprises an adhesive layer, and the adhesive layer is disposed between the cover and the collimation layer.

14. The optical fingerprint recognition device according to claim 13, wherein a refractive index of the liquid crystal molecule in a major axis direction is equal to each of a refractive index of the polymer, a refractive index of the adhesive layer, and a refractive index of the cover.

15. The optical fingerprint recognition device according to claim 14, wherein the optical fingerprint recognition device further comprises a backlight module, and the backlight module is disposed on one side of the substrate away from the light-sensitive element.

16. The optical fingerprint recognition device according to claim 12, wherein the optical fingerprint recognition device further comprises an organic light-emitting diode (OLED) display layer, and the OLED display layer is disposed between the cover and the collimation layer.

17. The optical fingerprint recognition device according to claim 16, wherein a refractive index of the liquid crystal molecule in a major axis direction is equal to each of a refractive index of the polymer, a refractive index of the OLED display layer, and a refractive index of the cover.

18. The optical fingerprint recognition device according to claim 17, wherein a side surface of the substrate close to the light-sensitive element is provided with a light filter layer.
